(19) United States
(12) Patent Application Publication
(10) Pub. No.: US 2026/0324349 A1
(43) Pub. Date: Oct. 15, 2026

(54) DIE FEED DEVICE

(71) Applicant: FUJI CORPORATION, Chiryu (JP)

(72) Inventors: Masaki MURAI, Nishio-shi (JP); Michiaki HATTORI, Yatomi-shi (JP); Yoshifumi OMI, Anjo-shi (JP)

(73) Assignee: FUJI CORPORATION, Chiryu (JP)

(21) Appl. No.: 19/482,177

(22) PCT Filed: Jun. 15, 2023
(86) PCT No.: PCT/JP2023/022246

§ 371 Date: Nov. 6, 2025

(51) Int. Cl. H10P 72/30; B25J 11/00; B25J 15/04; B25J 15/06; H10P 72/78

(52) U.S. Cl. CPC H10P 72/3212; B25J 11/0095; B25J 15/0441; B25J 15/0491; B25J 15/0616; H10P 72/78

(57) ABSTRACT

A die feed device includes a flip head including a first nozzle mounting section from which a first suction nozzle is detachably mounted, the flip head being configured to pick up a die with the first suction nozzle from a die assembly formed by dicing a wafer, an inverting mechanism configured to invert the flip head and switches a front and a back of the die picked up by the first suction nozzle, a feed head including a second nozzle mounting section from which a second suction nozzle is detachably mounted, the feed head being configured to pick up the die inverted by the flip head with the second suction nozzle and feed the die picked up by the second suction nozzle, and a nozzle station configured to accommodate both the first suction nozzle for exchange and the second suction nozzle for exchange.

### TECHNICAL FIELD

The present disclosure relates to a die feed device that feeds a die from a die assembly obtained by dicing a wafer.

### BACKGROUND ART

Conventionally, a technique related to a die feed device that takes out and feeds a die from a die assembly has been proposed. In this type of die feed device, for example, dies such as semiconductor chips are fed from the die assembly formed by dicing a wafer to which a dicing sheet is attached. Patent Literature 1 below describes a die feed device including a take-out head for taking out a die from a die assembly. The take-out head takes out a die attached to a dicing sheet with a nozzle, inverts the die, and delivers the die to a mounting head.

### CITATION LIST

### Patent Literature

Patent Literature 1: JP-A-2005-123638

### BRIEF SUMMARY

### Technical Problem

In the above-described die feed device, for example, in a case of feeding a power semiconductor such as an insulated gate bipolar transistor (IGBT), it is necessary to change the nozzle of the take-out head according to the size of the power semiconductor to be fed. Similarly, in the mounting head that receives the power semiconductor from the take-out head, it is necessary to change the nozzle according to the size of the die. Therefore, a technique that can appropriately manage exchange nozzles for two heads is necessary.

The present disclosure has been made in view of such circumstances, and an object of the present disclosure is to provide a die feed device capable of reducing a burden of managing an exchange nozzle in the die feed device that exchanges a suction nozzle of a flip head and a suction nozzle of a feed head.

### Solution to Problem

In order to solve the above problem, the present description discloses a die feed device including a flip head including a first nozzle mounting section from which a first suction nozzle is detachably mounted, the flip head being configured to pick up a die with the first suction nozzle from a die assembly formed by dicing a wafer, an inverting mechanism configured to invert the flip head and switches a front and a back of the die picked up by the first suction nozzle, a feed head including a second nozzle mounting section from which a second suction nozzle is detachably mounted, the feed head being configured to pick up the die inverted by the flip head with the second suction nozzle and feed the die picked up by the second suction nozzle, and a nozzle station configured to accommodate both the first suction nozzle for exchange and the second suction nozzle for exchange.

### Advantageous Effects

According to the present disclosure, both the first and second suction nozzles for exchange are accommodated in the nozzle station. For example, in a case of a configuration where the suction nozzle of a first one of the two heads including the flip head and the feed head is manually exchanged and the suction nozzle of a second one of the heads is automatically exchanged, since the suction nozzle is exchanged by a different method, management of the first and second suction nozzles may be complicated. In addition, for example, in a case of exchanging the first and second suction nozzles at different nozzle stations, it is necessary to move the two heads to different places and exchange the heads, which complicates a mechanism that moves the heads and control content of the heads. In addition, it is necessary to secure a space for installing each nozzle station. On the other hand, in the die feed device of the present disclosure, in one nozzle station, both the first suction nozzle for exchange mounted on the flip head and the second suction nozzle for exchange mounted on the feed head can be managed. Accordingly, the suction nozzles for exchange of the two heads can be collectively managed at one nozzle station and can be exchanged at one place. Further, by controlling each head, both the first and second suction nozzles can be automatically exchanged. In addition, the workload of managing the suction nozzles for exchange, such as an operation of replacing the suction nozzle for exchange of the nozzle station and confirming the suction nozzle housed in the nozzle station can be reduced.

### BRIEF DESCRIPTION OF DRAWINGS

FIG. 1 is a perspective view of a die feed device of an example.

FIG. 2 is a block diagram of the die feed device.

FIG. 3 is a perspective view of a flip mechanism, a transfer mechanism, and a nozzle station mechanism.

FIG. 4 is a perspective view of the flip mechanism.

FIG. 5 is a perspective view of the transfer mechanism, a shuttle mechanism, and the nozzle station mechanism.

FIG. 6 is a perspective view of the transfer mechanism as viewed from below.

FIG. 7 is a perspective view of the shuttle mechanism as viewed from above.

FIG. 8 is a perspective view of a nozzle station.

FIG. 9 is an exploded perspective view of a first nozzle mounting section and a first suction nozzle.

FIG. 10 is a perspective view of the first suction nozzle as viewed from a mounting surface side on which the first suction nozzle is mounted on the first nozzle mounting section.

FIG. 11 is a perspective view showing a state in which the first suction nozzle is accommodated in the nozzle station.

FIG. 12 is a view showing a first suction nozzle and a first nozzle mounting section of another example.

### DESCRIPTION OF EMBODIMENTS

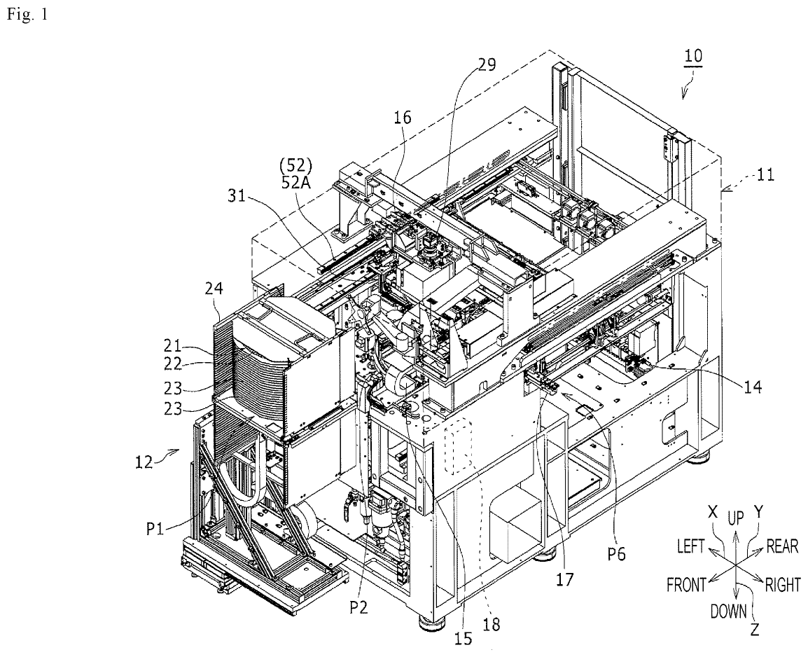

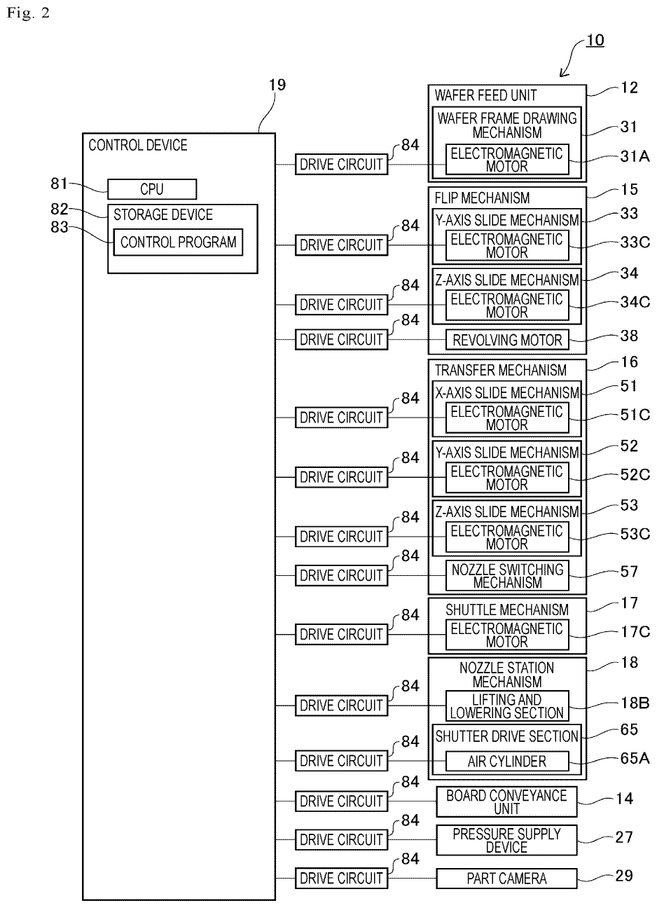

Hereinafter, an example of a die feed device of the present disclosure will be described with reference to the drawings. FIG. 1 shows a perspective view of die feed device 10 of the present example. FIG. 2 shows a block diagram of die feed device 10. As shown in FIG. 1, die feed device 10 includes device main body portion 11 and wafer feed unit 12. In FIG. 1, a device cover of device main body portion 11 is shown by a broken line, and the device cover of wafer feed unit 12 is not shown. In addition, in the following description, as shown in FIG. 1, a front-rear direction (or a Y-axis direction), a left-right direction (or an X-axis direction), and an up-down direction (or a Z-axis direction) are referred to based on a viewpoint of a user viewing die feed device 10 from the front. The front-rear direction and the left-right direction are directions parallel to a flat surface of a board conveyed by board conveyance unit 14 to be described later.

Wafer feed unit 12 is detachably mounted on a front end of device main body portion 11. Wafer feed unit 12 is mounted on device main body portion 11 to feed die (wafer component) 22 from die assembly 21 based on control of control device 19 (see FIG. 2) of device main body portion 11. Wafer feed unit 12 is a device that feeds die 22 to flip mechanism 15 and transfer mechanism 16 of device main body portion 11 and includes magazine 24 capable of housing multiple wafer frames 23. Wafer frames 23 are, for example, members for stretching and fixing a dicing sheet to which die assembly 21 is attached in a flat plate shape, and multiple wafer frames 23 are accommodated in magazine 24. Die assembly 21 is formed, for example, by dicing a wafer to which a dicing sheet is attached. A manufacturing process of die assembly 21 is not limited to the above-described method, and for example, a dicing sheet may be attached to a wafer which is diced (half-cut) only in half in a thickness direction, and after polishing a rear surface, the dicing sheet may be removed and separated by a laser or the like. That is, die assembly 21 may be an assembly of dies 22 obtained by dividing a wafer by dicing, and a manufacturing process thereof and a feeding method thereof are not limited. In addition, die assembly 21 may be in a state where die 22 is peeled from the dicing sheet in a case of being housed in magazine 24 and multiple dies 22 are arranged.

Wafer feed unit 12 includes wafer frame drawing mechanism 31 (see FIG. 2) for carrying out desired wafer frame 23 from magazine 24. Wafer frame drawing mechanism 31 has, for example, electromagnetic motor 31A (see FIG. 2) as a drive source, drives electromagnetic motor 31A based on control of control device 19, and carries out desired wafer frame 23 from multiple wafer frames 23 housed in magazine 24. Wafer frame drawing mechanism 31 moves desired wafer frame 23 in the front-rear direction to move wafer frame 23 between housing position P1 and die feeding position P2. The drive source of wafer frame drawing mechanism 31 is not limited to electromagnetic motor 31A and may be a second motor such as a linear motor. Alternatively, the drive source may be a fluid pressure cylinder such as an air cylinder and a hydraulic cylinder. Therefore, the drive source is not limited to a motor. The same applies to drive sources of a second device and a second mechanism.

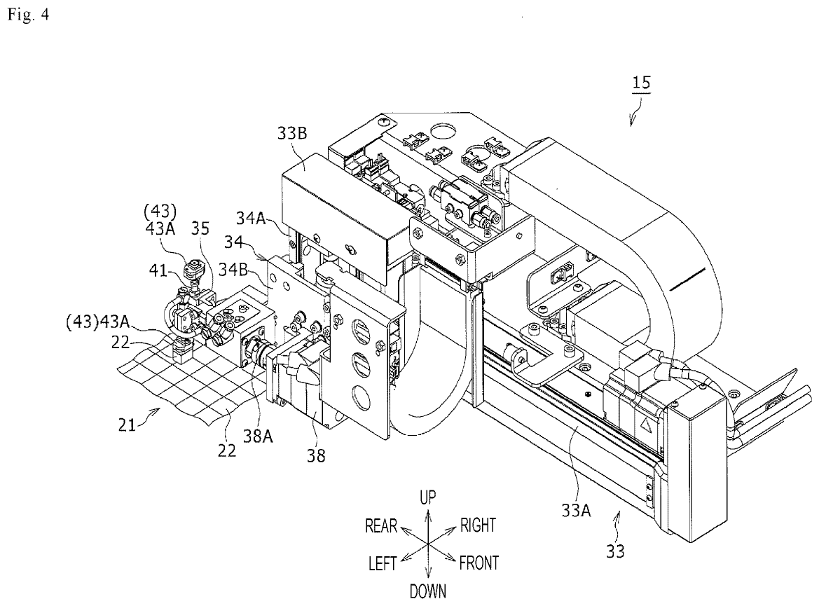

Housing position P1 is a position (position in magazine 24) where wafer frames 23 (die assembly 21) are housed in magazine 24. Die feeding position P2 is a position where first suction nozzle 43 (see FIG. 4) of flip mechanism 15 picks up die 22 from die assembly 21. In addition, wafer frame drawing mechanism 31 moves wafer frames 23 disposed at die feeding position P2 in the left-right direction to replace die 22 disposed below first suction nozzle 43 of flip mechanism 15. In addition, wafer frame drawing mechanism 31 includes, for example, a push-up mechanism (not shown) that drives a pin that pushes up, from below, a portion of die assembly 21, to which die 22 picked up by first suction nozzle 43 is attached, and a pot (not shown) that sucks the dicing sheet when die 22 is pushed up and peels desired die 22 from the dicing sheet to be fed to first suction nozzle 43.

In addition, die feed device 10 includes part camera 29 that images die 22 disposed in die assembly 21 from above. Part camera 29 outputs the captured image data to control device 19 (see FIG. 2). Control device 19 executes confirmation of the position of die 22 picked up by flip mechanism 15 or transfer mechanism 16 and correction of an error of the position based on the image data of part camera 29.

In addition, board conveyance unit 14, flip mechanism 15, transfer mechanism 16, shuttle mechanism 17, and nozzle station mechanism 18 are attached to device main body portion 11. Board conveyance unit 14 is a device that conveys a board (not shown) on which die 22 is mounted. Board conveyance unit 14 includes, for example, two lanes arranged in the front-rear direction and conveys the board in each lane. Die feed device 10 is connected to a device on an upstream side and a device on a downstream side in a board manufacturing line and can connect the lanes of board conveyance unit 14. In each lane, board conveyance unit 14 carries out the board carried in from the device on the upstream side to the device on the downstream side.

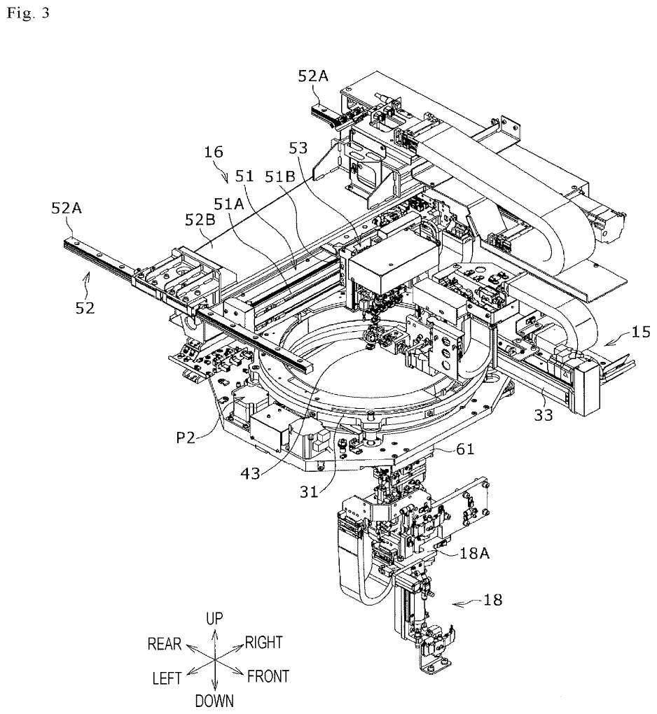

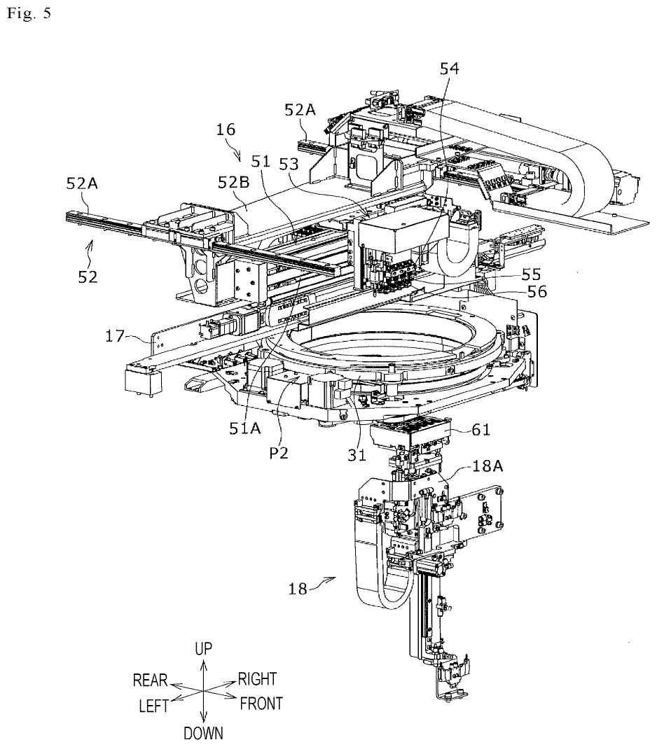

FIG. 3 is a perspective view of flip mechanism 15, transfer mechanism 16, and nozzle station mechanism 18. FIG. 4 is an enlarged view of flip mechanism 15. FIG. 3 and FIG. 5 to be described later show a state in which wafer frame 23 is removed from wafer frame drawing mechanism 31. In addition, FIG. 4 schematically shows die 22 of die assembly 21.

### Flip Mechanism 15

As shown in FIGS. 2 to 4, flip mechanism 15 is disposed above die assembly 21 disposed at die feeding position P2 and nozzle station mechanism 18. Flip mechanism 15 includes Y-axis slide mechanism 33, Z-axis slide mechanism 34, and flip head 35. Y-axis slide mechanism 33 includes Y-axis slide rail 33A and Y-axis slider 33B. Y-axis slide rail 33A is a rail provided on a left side surface of Y-axis slide mechanism 33 and extending in a direction parallel to the front-rear direction. Y-axis slider 33B is held by Y-axis slide rail 33A to be slidable in the Y-axis direction (front-rear direction). Y-axis slide mechanism 33 has electromagnetic motor 33C (see FIG. 2) and drives electromagnetic motor 33C based on control of control device 19 to move Y-axis slider 33B to any position in the front-rear direction.

Z-axis slide mechanism 34 has Z-axis slide rail 34A and Z-axis slider 34B. Z-axis slide rail 34A is a rail provided on a left side surface of Y-axis slider 33B and extending in a direction parallel to the up-down direction. Z-axis slider 34B is held by Z-axis slide rail 34A to be slidable in the Z-axis direction (up-down direction). Z-axis slide mechanism 34 has electromagnetic motor 34C (see FIG. 2) and drives electromagnetic motor 34C based on control of control device 19 to move Z-axis slider 34B to any position in the up-down direction.

Revolving motor 38 for revolving flip head 35 is attached to the left side surface of Z-axis slider 34B. Revolving motor 38 is, for example, an electromagnetic motor and is driven based on control of control device 19 to rotate output shaft 38A. Flip head 35 is attached to a tip portion of output shaft 38A and rotates based on driving of revolving motor 38. For example, revolving motor 38 revolves flip head 35 around an axis parallel to the front-rear direction (Y-axis direction) as a rotation axis.

Flip head 35 is provided with pair of first nozzle mounting sections 41. First suction nozzle 43 can be mounted one by one on pair of first nozzle mounting sections 41. Therefore, two first suction nozzles 43 can be mounted on flip head 35. The number of first nozzle mounting sections 41 provided in flip head 35 and the number of first suction nozzles 43 that can be mounted on flip head 35 are not limited to two, may be one, or three or more. In addition, multiple first suction nozzles 43 may be configured to be mounted on one first nozzle mounting section 41. In addition, as will be described later, first suction nozzle 43 can be exchanged with first suction nozzle 43 for exchange housed in nozzle station 61 of nozzle station mechanism 18. Therefore, in the following description, in a case where first suction nozzles 43 are distinguished from each other, first suction nozzle 43 mounted on first nozzle mounting section 41 is referred to as first suction nozzle 43A, and first suction nozzle 43 for exchange accommodated in nozzle station 61 is referred to as first suction nozzle 43B. In addition, two first suction nozzles 43A and 43B are collectively referred to as first suction nozzle 43. In addition, the same applies to second suction nozzle 56 of transfer head 54 to be described later.

Die feed device 10 includes pressure supply device 27 (see FIG. 2) that supplies air at a predetermined pressure to each device. Each of pair of first nozzle mounting sections 41 is connected to pressure supply device 27. For example, first suction nozzle 43 picks up die 22 by being supplied with a negative pressure from pressure supply device 27 via first nozzle mounting section 41 and releases picked up die 22 by being supplied with a positive pressure. As described above, flip head 35 is attached to Z-axis slider 34B via revolving motor 38. Therefore, flip head 35 can be moved to any position in the front-rear direction and the up-down direction based on driving of Y-axis slide mechanism 33 and Z-axis slide mechanism 34. In addition, as described above, wafer frame drawing mechanism 31 can move wafer frame 23 disposed at die feeding position P2 in the left-right direction. Thus, flip head 35 can pick up desired die 22 from die assembly 21 with first suction nozzle 43.

First nozzle mounting sections 41 extend outward in a radial direction from a center side of rotation of flip head 35, and first suction nozzle 43 is mounted on a tip. A first one of pair of first nozzle mounting sections 41 is, for example, point-symmetrical to a second one of first nozzle mounting sections 41 with respect to a rotation center of flip head 35. Therefore, each of pair of first nozzle mounting sections 41 is provided at a rotation position shifted by 180 degrees in a rotation direction (circumferential direction) of flip head 35. When the first one of pair of first nozzle mounting sections 41 has a tip facing upward, the second one of the first nozzle mounting sections 41 has a tip facing downward. First nozzle mounting section 41 picks up die 22 from die assembly 21 with the tip facing downward. Die 22 picked up by first nozzle mounting sections 41 is, for example, switched (inverted) front and back sides by rotating flip head 35 by 180 degrees and is in a state where a non-mounting surface faces upward. Transfer mechanism 16 acquires die 22 from first nozzle mounting sections 41 facing upward.

### Transfer Mechanism 16

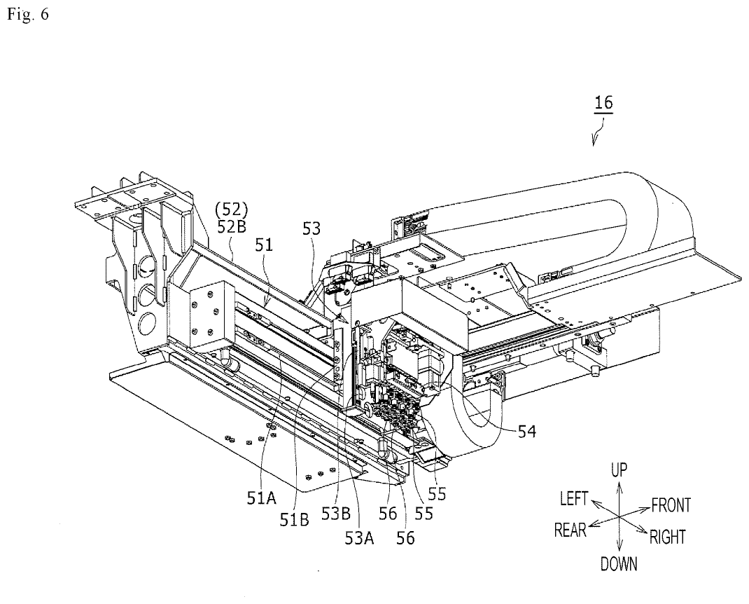

Next, transfer mechanism 16 will be described. FIG. 5 is a perspective view of transfer mechanism 16, shuttle mechanism 17, and nozzle station mechanism 18. FIG. 6 is a perspective view of transfer mechanism 16 as viewed from below. As shown in FIGS. 3, 5, and 6, transfer mechanism 16 is disposed on a rear side of flip mechanism 15. Transfer mechanism 16 includes X-axis slide mechanism 51, Y-axis slide mechanism 52, Z-axis slide mechanism 53, and transfer head 54.

Y-axis slide mechanism 52 has pair of Y-axis slide rails 52A and Y-axis slider 52B. Each of pair of Y-axis slide rails 52A is provided on an upper portion of device main body portion 11 in the left-right direction. Pair of Y-axis slide rails 52A is disposed parallel to each other with a predetermined interval therebetween in the left-right direction and each extends in the direction parallel to the front-rear direction. Y-axis slider 52B extends in the left-right direction to straddle both of pair of Y-axis slide rails 52A. Both ends of Y-axis slider 52B in the left-right direction are held by pair of Y-axis slide rails 52A, respectively. Therefore, Y-axis slider 52B is held by pair of Y-axis slide rails 52A to be slidable in the front-rear direction. Y-axis slide mechanism 52 has electromagnetic motor 52C (see FIG. 2) and drives electromagnetic motor 52C based on control of control device 19 to move Y-axis slider 52B to any position in the front-rear direction.

X-axis slide mechanism 51 is attached to Y-axis slider 52B and has X-axis slide rail 51A and X-axis slider 51B. X-axis slide rail 51A is a rail provided on a front surface of Y-axis slider 52B and extending in a direction parallel to the left-right direction. X-axis slider 51B is held by X-axis slide rail 51A to be slidable in the X-axis direction (left-right direction). X-axis slide mechanism 51 has electromagnetic motor 51C (see FIG. 2) and drives electromagnetic motor 51C based on control of control device 19 to move X-axis slider 51B to any position in the left-right direction.

Similarly, Z-axis slide mechanism 53 has Z-axis slide rail 53A and Z-axis slider 53B. Z-axis slide rail 53A is a rail provided on a front surface of X-axis slider 51B and extending in the direction parallel to the up-down direction. Z-axis slider 53B is held by Z-axis slide rail 53A to be slidable in the Z-axis direction and moves to any position in the up-down direction based on driving of electromagnetic motor 53C (see FIG. 2).

Transfer head 54 is attached to a front surface of Z-axis slider 53B. Therefore, transfer head 54 can be moved to any position in the front-rear direction, the left-right direction, and the up-down direction based on driving of X-axis slide mechanism 51, Y-axis slide mechanism 52, and Z-axis slide mechanism 53. Transfer head 54 is provided with multiple second nozzle mounting sections 55. In transfer head 54 of the present example, eight second nozzle mounting sections 55 are provided. In eight second nozzle mounting sections 55, for example, four second nozzle mounting sections 55 arranged in the left-right direction at a predetermined pitch are provided in two rows in the front-rear direction. Second suction nozzle 56 is detachably mounted to each of eight second nozzle mounting sections 55. Transfer head 54 picks up die 22 inverted by flip head 35 from first suction nozzle 43 by eight second suction nozzles 56. Alternatively, transfer head 54 directly picks up die 22 from die assembly 21 by second suction nozzle 56 for die 22 that is not inverted (flipped). Transfer head 54 feeds die 22 picked up by second suction nozzle 56 to shuttle mechanism 17. The number of second nozzle mounting sections 55 provided in transfer head 54, disposition of second nozzle mounting sections 55, and the number of second suction nozzles 56 that can be mounted on transfer head 54 are examples. For example, transfer head 54 may include only one second nozzle mounting section 55.

Each of multiple second nozzle mounting sections 55 is connected to pressure supply device 27 (see FIG. 2). Similarly to first suction nozzle 43, second suction nozzle 56 picks up die 22 by being supplied with a negative pressure via second nozzle mounting sections 55 and releases picked up die 22 by being supplied with a positive pressure. In addition, transfer head 54 is provided with nozzle switching mechanism 57 (see FIG. 2) that individually lifts and lowers multiple second nozzle mounting sections 55. Nozzle switching mechanism 57 includes, for example, a ball screw mechanism or the like and individually changes positions of multiple second nozzle mounting sections 55 in the up-down direction. As a result, a position of any second suction nozzle 56 in the up-down direction can be changed to switch second suction nozzle 56 to be picked up or released.

### Shuttle Mechanism 17

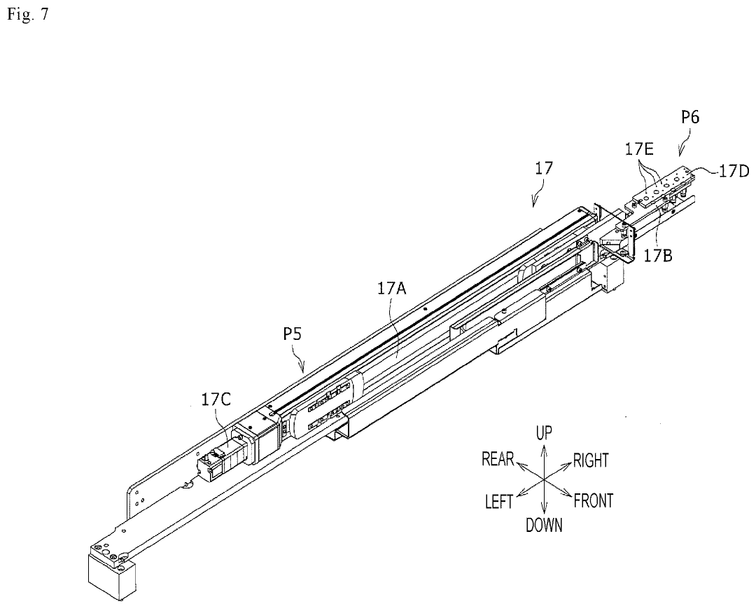

As shown in FIG. 5, shuttle mechanism 17 is disposed above wafer frame drawing mechanism 31 and below transfer mechanism 16 in up-down direction. As shown in FIG. 7, shuttle mechanism 17 has X-axis slide rail 17A and X-axis slider 17B. X-axis slide rail 17A is a rail extending in the direction parallel to the left-right direction. X-axis slider 17B is held by X-axis slide rail 17A to be slidable in the left-right direction. Shuttle mechanism 17 moves, for example, X-axis slider 17B in the left-right direction based on driving of electromagnetic motor 17C and moves X-axis slider 17B between receiving position P5 and delivery position P6.

Receiving position P5 is a position at a left end portion of X-axis slide rail 17A and is a position for receiving die 22 from second suction nozzle 56 of transfer head 54. Delivery position P6 is a position at a right end portion of X-axis slide rail 17A. As shown in FIG. 1, a right end portion of X-axis slide rail 17A protrudes rightward from an opening formed in a right side surface of device main body portion 11 and is disposed outside device main body portion 11. For example, a component mounter (not shown) is disposed on a right side of die feed device 10. The component mounter carries a board in from board conveyance unit 14 of die feed device 10, receives die 22 fed from shuttle mechanism 17 of die feed device 10 at delivery position P6, and mounts die 22 on the board carried in.

As shown in FIG. 7, shuttle 17D is attached to an upper surface of X-axis slider 17B. Shuttle 17D is, for example, a metal plate and is attached to X-axis slider 17B with a flat surface facing upward. Multiple intake ports 17E are formed in shuttle 17D. Multiple intake ports 17E are formed at positions corresponding to the positions of eight second suction nozzles 56 of transfer head 54, and a total of eight intake ports 17E are provided. Eight intake ports 17E are configured such that four intake ports 17E arranged in the left-right direction are arranged in each of two rows in the front-rear direction in accordance with the positions of eight second suction nozzles 56. Each of eight intake ports 17E is connected to pressure supply device 27 (see FIG. 2) and is supplied with a negative pressure from pressure supply device 27 to pick up die 22 when receiving die 22 from second suction nozzle 56.

### Nozzle Station Mechanism 18

Next, nozzle station mechanism 18 will be described. As shown in FIGS. 3 and 5, in nozzle station mechanism 18, nozzle station 61 is attached to an upper end portion of main body portion 18A. Main body portion 18A is provided with lifting and lowering section 18B (see FIG. 2). Lifting and lowering section 18B includes, for example, an electromagnetic motor, a ball screw mechanism, or the like and slides nozzle station 61 in the direction parallel to the up-down direction based on control of control device 19 to change the height of nozzle station 61.

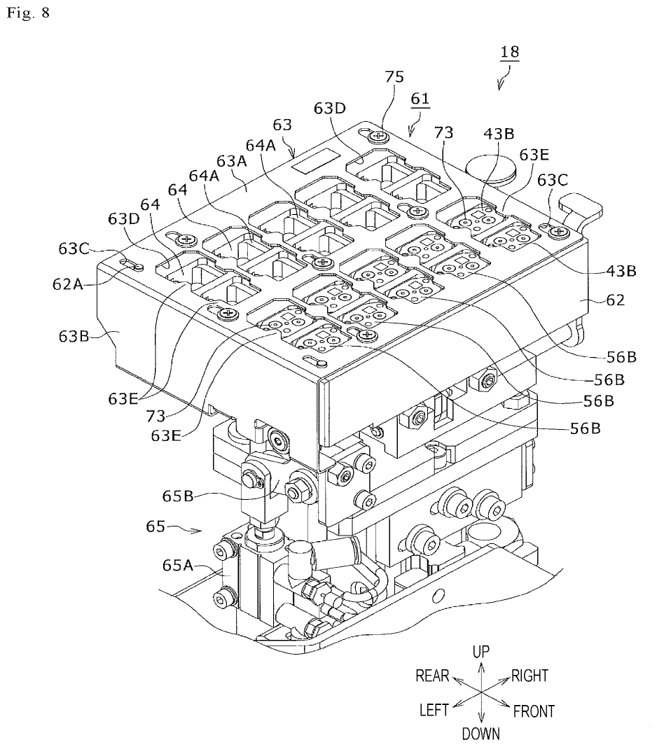

FIG. 8 is an enlarged view of nozzle station 61. As shown in FIG. 8, nozzle station 61 includes accommodating box 62 and shutter 63. Accommodating box 62 has, for example, a rectangular parallelepiped shape that has a predetermined thickness in the up-down direction and that is long in the left-right direction and the front-rear direction. Multiple nozzle accommodating portions 64 are formed in accommodating box 62. In the present example, twenty nozzle accommodating portions 64 are formed in accommodating box 62. First and second suction nozzles 43 and 56 can be housed in each of twenty nozzle accommodating portions 64.

Herein, first nozzle mounting sections 41 and second nozzle mounting sections 55 of the present example have a structure in which a portion to which the suction nozzle is attached is common. Therefore, second suction nozzle 56 is compatible with first suction nozzle 43. First and second suction nozzles 43 and 56 are exchanged with another suction nozzle in which the diameter of a hole for suction, the size of a portion in contact with die 22, and the like vary depending on the size of die 22 to be picked up or the like. However, the same first and second suction nozzles 43 and 56 can be used for the same type of die 22 and can be exchanged with each other.

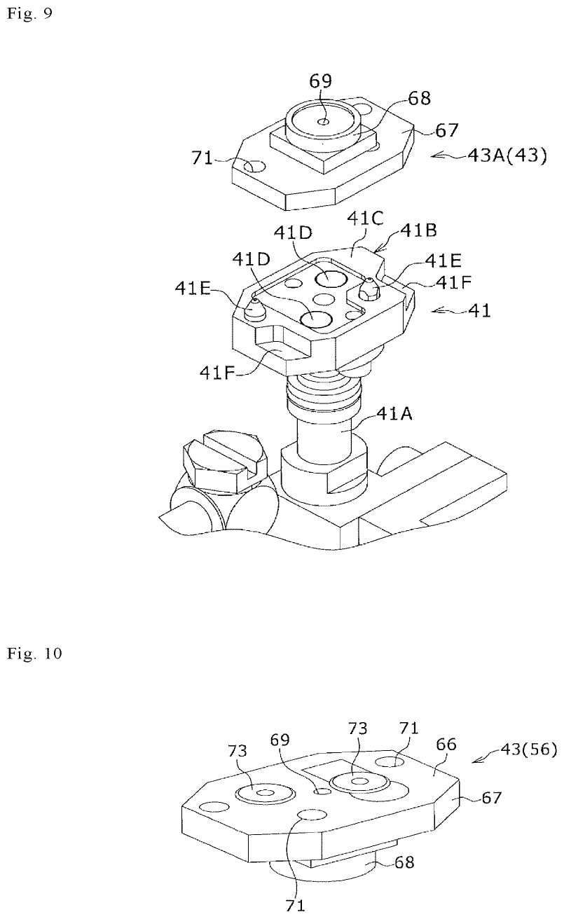

Specifically, FIG. 9 is an exploded perspective view of first nozzle mounting section 41 and first suction nozzle 43A. As described above, a structure of a portion of second nozzle mounting section 55 on which second suction nozzle 56 is mounted is the same as a structure of a portion of first nozzle mounting section 41 on which first suction nozzle 43 is mounted. Therefore, description of the portion of second nozzle mounting section 55 on which second suction nozzle 56 is mounted and detailed description of second suction nozzle 56 will be omitted. In addition, the structure of a mounting portion of first nozzle mounting section 41 may be different from a structure of a mounting portion of second nozzle mounting section 55. Therefore, first suction nozzle 43 may be a structure in which a mounting method different from a mounting method of second suction nozzle 56 is adopted (for example, see FIG. 12).

As shown in FIG. 9, first nozzle mounting section 41 includes shaft portion 41A and mounting section 41B. Shaft portion 41A is, for example, a substantially columnar member and is a portion that revolves based on driving of revolving motor 38 (see FIG. 2). Mounting section 41B is provided at a tip of shaft portion 41A and rotates together with shaft portion 41A. Mounting section 41B has a substantially plate shape having a small thickness (width) in an axial direction (up-down direction in FIG. 9) of shaft portion 41A. Mounting section 41B has a substantially octagonal shape as viewed from a first side in the axial direction. The tip of shaft portion 41A is attached to an inner surface of mounting section 41B in the axial direction. An outer peripheral surface which is an outer surface of mounting section 41B in the axial direction is mounting surface 41C on which first suction nozzle 43A is mounted. Mounting section 41B is provided with multiple (two in the present example) magnets 41D and multiple (two in the present example) projections 41E. Magnets 41D have, for example, a disk shape and are attached to mounting section 41B in a state in which a magnetic pole surface is exposed from mounting surface 41C. In addition, protrusions 41E are attached to mounting section 41B in a state of protruding outward in the axial direction from mounting surface 41C and have a shape tapered from a base end portion toward a tip portion.

FIG. 10 is a perspective view of first suction nozzle 43 as viewed from a mounting surface 66 side attached to mounting section 41B. As shown in FIGS. 9 and 10, first suction nozzle 43 includes mounting section 67 and pick-up portion 68. Mounting section 67 has a thin plate shape. An outer shape of mounting section 67 is a substantially octagonal shape having the same size as mounting section 41B of first nozzle mounting section 41. Pick-up portion 68 is provided on a surface of mounting section 67 on a tip side. Pick-up portion 68 has, for example, a shape in which a substantially disk-shaped member is provided on the tip side (outside) of a thin square member. The shape of mounting section 67 or pick-up portion 68 is changed according to the size and the shape of die 22 to be picked up.

Intake port 69 for suction is formed in a central portion of mounting section 67 and pick-up portion 68. Intake port 69 is a hole having a circular cross section penetrating mounting section 67 and pick-up portion 68 in the thickness direction. In addition, multiple (two in the present example) insertion holes 71 penetrating in the thickness direction are formed in mounting section 67. Insertion holes 71 are, for example, holes having a circular cross section and are formed in accordance with the positions of projections 41E provided on mounting section 41B. In a state in which first suction nozzle 43 is mounted on first nozzle mounting section 41, projections 41E are inserted into two insertion holes 71, respectively. In other words, by inserting projections 41E into insertion holes 71, a positional shift of first suction nozzle 43 with respect to first nozzle mounting section 41 is suppressed.

Multiple (two in the present example) magnetic members 73 are attached to mounting surface 66 of mounting section 67. Two magnetic members 73 are, for example, columnar or disk-shaped metal members and are fixed to be embedded in mounting section 67 in a state where end surfaces thereof are exposed from mounting surface 66. Two magnetic members 73 are provided in accordance with positions of magnets 41D of first nozzle mounting sections 41. When first suction nozzle 43 is attached to first nozzle mounting section 41, the position of magnetic member 73 with respect to magnets 41D is aligned by inserting projections 41E into insertion holes 71. Then, two magnets 41D attract and hold first suction nozzle 43 to mounting section 41B by attracting two magnetic members 73, respectively, with a magnetic force.

Configurations of magnets 41D and magnetic members 73 described above are examples. With a configuration where magnets 41D are provided on first nozzle mounting section 41 and magnetic members 73 are provided on first suction nozzle 43, in a case where the number of first suction nozzles 43 for exchange is increased, the number of magnets required can be reduced as compared with a configuration where the magnet is provided on first suction nozzle 43, and costs can be reduced. However, a configuration in which the magnetic member is provided on first nozzle mounting section 41 and the magnet is provided in first suction nozzle 43 may be adopted. Alternatively, magnets may be provided on both first nozzle mounting section 41 and first suction nozzle 43, and the magnets may magnetically attract each other. In addition, a method of holding first suction nozzle 43 with respect to first nozzle mounting section 41 is not limited to a magnetic force method using a magnet (see FIG. 12).

As shown in FIG. 8, for example, five of twenty nozzle accommodating portions 64 are provided in the left-right direction and are arranged in four rows in the front-rear direction. Nozzle accommodating portions 64 have a shape capable of holding first and second suction nozzles 43 and 56 with pick-up portion 68 facing downward. Nozzle accommodating portions 64 are holes whose upper portion is opened, and step portions 64A for placing mounting section 67 are formed on both sides in the left-right direction, respectively. Each of first and second suction nozzles 43 and 56 is housed in a state where pick-up portion 68 is inserted into a central recessed portion and an end portion of mounting section 67 in the left-right direction is placed on each of pair of step portions 64A. In the state shown in FIG. 8, first and second suction nozzles 43B and 56B for exchange are accommodated in the ten nozzle accommodating portions on a front side. First and second suction nozzles 43B and 56B are housed in nozzle accommodating portions 64 in a state where mounting surface 66 to which magnetic member 73 is attached faces upward. Ten first and second suction nozzles 43B and 56B for exchange are, for example, of the same type and are used for the same type of die 22.

Shutter 63 has a substantially L-shape formed by bending a thin metal plate by 90 degrees and has upper surface portion 63A covering an upper surface of accommodating box 62 and a side surface portion 63B covering a left side surface of accommodating box 62. Upper surface portion 63A has a substantially rectangular plate shape that is long in the left-right direction. In shutter 63, multiple elongated holes 63C into which screws 75 screwed into accommodating box 62 and projections 62A protruding upward from accommodating box 62 are inserted are formed in upper surface portion 63A, and shutter 63 is held by accommodating box 62 to be slidable in the front-rear direction. Shutter drive section 65 that slides shutter 63 in the front-rear direction is provided at the upper end portion of main body portion 18A. Shutter drive section 65 has, for example, air cylinder 65A and link member 65B connected to an output rod of air cylinder 65A. Shutter drive section 65 drives air cylinder 65A based on control of control device 19 to move shutter 63 in the front-rear direction via link member 65B.

Multiple opening portions 63D and multiple engaging portions 63E are formed in upper surface portion 63A. Multiple opening portions 63D are holes penetrating upper surface portion 63A, and twenty opening portions 63D are formed in accordance with positions of twenty nozzle accommodating portions 64. Opening portions 63D are formed in accordance with the sizes of first and second suction nozzles 43 and 56, and in a state in which slide positions in the front-rear direction are aligned with nozzle accommodating portions 64, openings of nozzle accommodating portions 64 are exposed upward. In a state in which the positions are aligned, first and second suction nozzles 43 and 56 can be taken in and out of nozzle accommodating portions 64 through opening portions 63D.

Two opening portions 63D adjacent to each other in the front-rear direction are connected to each other. Two engaging portions 63E are formed on the front side of each opening portion 63D. Pair of engaging portions 63E has a shape protruding inward from both sides in the left-right direction. As shown in FIG. 9, pair of recessed portions 41F are formed in mounting section 41B. Pair of recessed portions 41F has a shape in which mounting surface 41C is recessed from the outside toward the inside in the axial direction and is a groove in which an outer surface in the left-right direction and a front surface (a surface on the front side in FIG. 9) are eliminated. Recessed portions 41F are formed to have depths at which engaging portions 63E can be inserted in a state in which first suction nozzle 43 is mounted on mounting surface 41C.

For example, in a case where shutter 63 is moved to a front end by shutter drive section 65, opening portions 63D of shutter 63 are in a state of being disposed above nozzle accommodating portions 64. In addition, in a case where shutter 63 is moved to a rear end by shutter drive section 65, shutter 63 is in a state in which pair of engaging portions 63E are disposed above nozzle accommodating portions 64. For example, in a case of accommodating first suction nozzle 43A, first nozzle mounting sections 41 insert first suction nozzles 43A into nozzle accommodating portions 64 through opening portions 63D. Next, in a case where shutter drive section 65 is driven and shutter 63 is slid to the rear end, pair of engaging portions 63E are inserted into pair of recessed portions 41F, respectively. As flip head 35 is lifted in this state, pair of engaging portions 63E is engaged with first suction nozzle 43A, and first suction nozzle 43A is separated from first nozzle mounting section 41. Separated first suction nozzle 43A is accommodated in nozzle accommodating portion 64.

### Configuration of Control Device 19 and Feeding Operation of Die 22

FIG. 2 is a block diagram of control device 19. Control device 19 includes CPU 81 and storage device 82 and is a processing device mainly include a computer. Storage device 82 is configured by combining, for example, RAM, ROM, a hard disk, and the like. Storage device 82 stores control program 83 for controlling die feed device 10. Control device 19 is connected to each of devices such as wafer feed unit 12, flip mechanism 15, transfer mechanism 16, shuttle mechanism 17, nozzle station mechanism 18, board conveyance unit 14, pressure supply device 27, and part camera 29 via multiple drive circuits 84. Control device 19 executes control program 83 in CPU 81 and controls an operation of die feed device 10 by controlling each device described above via drive circuits 84. Drive circuits 84 are, for example, a motor driver circuit that drives a motor or an external interface that connects an external device.

Control device 19 causes each device to execute feeding of die 22. In the following description, devices controlled by control device 19 may be simply referred to as device names. For example, the description that “wafer frame drawing mechanism 31 carries out desired wafer frame 23 from magazine 24 to die feeding position P2” means that “control device 19 executes control program 83 in CPU 81, causes wafer frame drawing mechanism 31 via drive circuits 84 to carry desired wafer frame 23 out from magazine 24 to die feeding position P2.”

First, before starting feeding of die 22, control device 19 causes wafer feed unit 12 to place wafer frame 23 corresponding to the type of die 22 to be fed at die feeding position P2. Wafer frame drawing mechanism 31 carries desired wafer frame 23 out from magazine 24 to die feeding position P2 based on control of control device 19. Flip mechanism 15 drives Y-axis slide mechanism 33 to move above die assembly 21 at die feeding position P2 and drives Z-axis slide mechanism 34 to lower first suction nozzle 43 and pick up die 22. Control device 19 drives wafer frame drawing mechanism 31 or Y-axis slide mechanism 33 to move flip head 35 above die 22 to be picked up next. Flip mechanism 15 drives revolving motor 38 to replace the position of pair of first suction nozzles 43 and picks up die 22 with remaining first suction nozzles 43.

In a case where die 22 is picked up by both of pair of first suction nozzles 43, flip mechanism 15 moves flip head 35 to a position where die 22 is delivered to transfer head 54 of transfer mechanism 16 (position in FIG. 3). Transfer mechanism 16 drives nozzle switching mechanism 57 to lower second suction nozzle 56 that receives die 22 from flip head 35. Flip mechanism 15 delivers die 22 from first suction nozzle 43 facing upward to second suction nozzle 56 of transfer head 54. Flip mechanism 15 rotates flip head 35 to replace the position of pair of first suction nozzles 43. Transfer mechanism 16 drives X-axis slide mechanism 51 and Y-axis slide mechanism 52 to change second suction nozzle 56 positioned above first suction nozzle 43 and drives nozzle switching mechanism 57 to lower second suction nozzle 56 to be received. Flip mechanism 15 delivers die 22 from remaining first suction nozzle 43 to another second suction nozzle 56. Flip mechanism 15 and transfer mechanism 16 repeatedly perform the above-described operation to cause all of eight second suction nozzles 56 to pick up die 22.

In a case where eight dies 22 are completely picked up, transfer mechanism 16 drives X-axis slide mechanism 51 and Y-axis slide mechanism 52 to move transfer head 54 to above receiving position P5 of shuttle mechanism 17. Shuttle mechanism 17 drives electromagnetic motor 17C to place X-axis slider 17B at receiving position P5. Transfer mechanism 16 drives Z-axis slide mechanism 53 to lower transfer head 54, and collectively places dies 22 picked up by eight second suction nozzles 56 on shuttle 17D. Shuttle mechanism 17 sucks air from intake ports 17E and picks up die 22 with shuttle 17D. Shuttle mechanism 17 drives electromagnetic motor 17C to move X-axis slider 17B from receiving position P5 to delivery position P6 with die 22 picked up with shuttle 17D. The component mounter disposed on the right side of die feed device 10 performs an operation of picking up die 22 from shuttle 17D disposed at delivery position P6 with the mounting head (not shown) and mounting die 22 on the board.

### Exchange of First and Second Suction Nozzles 43 and 56

Control device 19 executes exchange of first and second suction nozzles 43 and 56 according to the type of die 22. For example, exchange of first and second suction nozzles 43 and 56 is executed in accordance with a so-called changeover in which the type of board which is a production target to be conveyed by board conveyance unit 14 is changed. First, for example, control device 19 causes flip mechanism 15 to move flip head 35 to a retracted position and causes transfer mechanism 16 to move transfer head 54 to the retracted position.

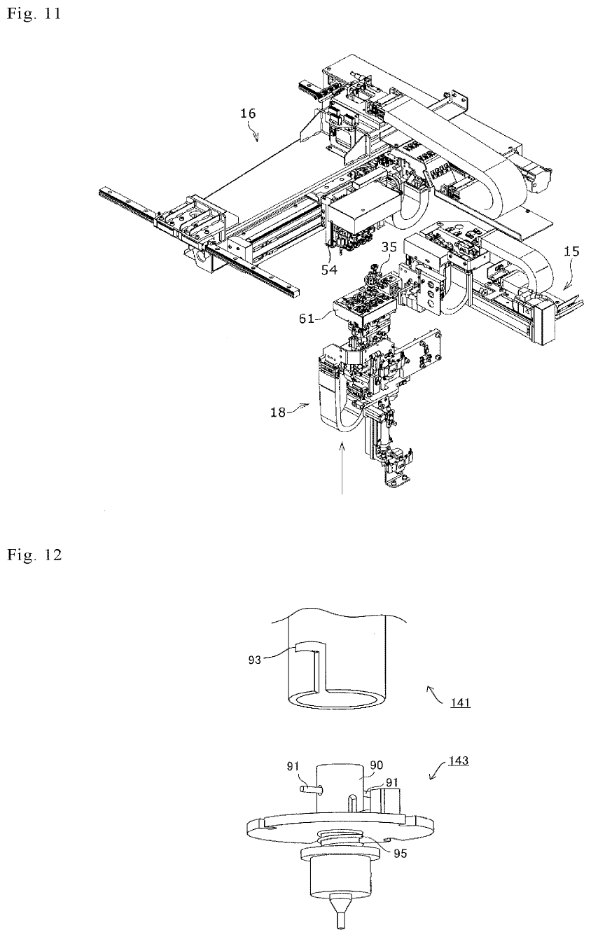

FIG. 11 shows a state in which first suction nozzle 43A is accommodated in nozzle station 61. Wafer frame drawing mechanism 31 moves wafer frames 23 from die feeding position P2 to housing position P1 and houses wafer frames 23 in magazine 24. As shown in FIG. 11, wafer frames 23 are not disposed between flip mechanism 15 and nozzle station mechanism 18 in the up-down direction. Flip mechanism 15 drives Y-axis slide mechanism 33 to move first suction nozzle 43A to a position above nozzle station 61 in the front-rear direction. Nozzle station mechanism 18 drives lifting and lowering section 18B to lift nozzle station 61 to a position (position in FIG. 11) where first suction nozzle 43 is exchanged.

In nozzle station 61 of the present example, nozzle accommodating portions 64 that accommodate first and second suction nozzles 43 and 56 are determined in advance, and different nozzle accommodating portions 64 are set to be used. Accordingly, a movement shaft of flip mechanism 15 can be reduced. More specifically, as shown in FIG. 8, twenty nozzle accommodating portions 64 are provided such that ten are provided on the front side and ten are provided on the rear side. For example, first and second suction nozzles 43 and 56 accommodated in ten nozzle accommodating portions 64 on the front side are used for die 22 of a first type, and first and second suction nozzles 43 and 56 accommodated in ten nozzle accommodating portions 64 on the rear side are used for die 22 of a second type different from the first type. In addition, among ten first and second suction nozzles 43 and 56 of the first type, eight nozzles on the left side are used as second suction nozzles 56, and two nozzles on the right side are used as first suction nozzles 43. Similarly, among ten first and second suction nozzles 43 and 56 of the second type, eight nozzles on the left side are used as second suction nozzles 56, and two nozzles on the right side are used as first suction nozzles 43.

With this setting, among twenty nozzle accommodating portions 64, four nozzle accommodating portions 64 arranged in the front-rear direction in the rightmost row are used as nozzle accommodating portions 64 for accommodating first suction nozzles 43. In other words, since flip mechanism 15 using first suction nozzles 43 can be exchanged when first suction nozzles 43 can be disposed at the positions of four nozzle accommodating portions 64 arranged in the front-rear direction, an operation in the left-right direction is not required in an exchange operation. In the present example, flip mechanism 15 does not include a slide mechanism that moves in the left-right direction (X-axis direction), and a position in the left-right direction is fixed. In addition, nozzle station mechanism 18 does not include a mechanism that moves in the left-right direction or the front-rear direction, and the position of nozzle station 61 (nozzle accommodating portions 64) in the left-right direction and the front-rear direction is fixed. As a result, the number of movement shafts required for flip mechanism 15 and nozzle station mechanism 18 can be reduced, manufacturing costs can be reduced, and the size of the device can be reduced.

Flip mechanism 15 accommodates two first suction nozzles 43A mounted on flip head 35 in vacant nozzle accommodating portions 64 in four nozzle accommodating portions 64 on the rightmost side described above, and first suction nozzles 43B for exchange take out and mounted from remaining two nozzle accommodating portions 64. More specifically, in accordance with the exchange operation of first and second suction nozzles 43 and 56, nozzle station mechanism 18 slides shutter 63 to the front end and aligns opening portion 63D of shutter 63 with positions above nozzle accommodating portions 64. While the exchange operation of first and second suction nozzles 43 and 56 is not performed, a position where shutter 63 is disposed is not particularly limited. For example, while the exchange operation of first and second suction nozzles 43 and 56 is not performed, nozzle station mechanism 18 may place shutter 63 at the position of the front end and place opening portion 63D above nozzle accommodating portions 64 so that a worker easily exchanges first and second suction nozzles 43B and 56B for exchange of nozzle station 61 with other suction nozzles. Alternatively, while the exchange operation of first and second suction nozzles 43 and 56 is not performed, nozzle station mechanism 18 may place shutter 63 at the position of the rear end and place pair of engaging portions 63E above nozzle accommodating portions 64 to make it difficult to take out first and second suction nozzles 43B and 56B. Nozzle station mechanism 18 may move shutter 63 in response to an operation instruction from the worker.

In a case where first suction nozzles 43A are inserted into nozzle accommodating portions 64, nozzle station mechanism 18 drives shutter drive section 65 to move shutter 63 to the rear end and inserts engaging portions 63E (see FIG. 8) into recessed portions 41F (see FIG. 9) of first nozzle mounting sections 41 being inserted. After engaging portions 63E are inserted, flip mechanism 15 drives Z-axis slide mechanism 34 to lift first nozzle mounting sections 41. Accordingly, first suction nozzles 43A are separated from first nozzle mounting sections 41 by engaging portions 63E from a state of being picked up by magnetic members 73 and are accommodated in nozzle accommodating portions 64. Flip mechanism 15 rotates flip head 35 to house first suction nozzles 43A of remaining first nozzle mounting sections 41 in another nozzle accommodating portion 64.

Next, in a case where first suction nozzles 43B for exchange are mounted on first nozzle mounting sections 41, nozzle station mechanism 18 drives shutter drive section 65 to move shutter 63 to the front end so that opening portions 63D are moved above nozzle accommodating portions 64. Flip mechanism 15 drives Y-axis slide mechanism 33 to align positions of first nozzle mounting sections 41 with positions of nozzle accommodating portions 64 where first suction nozzles 43B are accommodated. Flip mechanism 15 drives Z-axis slide mechanism 34 to lower first nozzle mounting sections 41. Magnetic member 73 (see FIG. 10) is picked up by magnets 41D (see FIG. 9) of first nozzle mounting sections 41, and first suction nozzles 43B accommodated in nozzle accommodating portions 64 are mounted on first nozzle mounting sections 41. In this case, projections 41E are inserted into insertion holes 71, so that a position of mounting section 67 is aligned with respect to mounting section 41B. That is, positional shifts of first suction nozzles 43B with respect to first nozzle mounting sections 41 are corrected, and first suction nozzles 43B are mounted at correct positions. Flip mechanism 15 rotates flip head 35 to mount first suction nozzles 43B also on remaining first nozzle mounting sections 41.

Next, transfer mechanism 16 exchanges second suction nozzles 56A of transfer head 54. In the following description of the exchange operation of second suction nozzle 56, the same content as that of first suction nozzles 43 described above will not be described. In a case where exchange of first suction nozzles 43 is completed, flip mechanism 15 moves to, for example, the foremost retracted position in a movable range in the front-rear direction. Transfer mechanism 16 drives X-axis slide mechanism 51 and Y-axis slide mechanism 52 to move transfer head 54 to a position above nozzle station 61.

As described above, for exchange of second suction nozzle 56, eight nozzle accommodating portions 64 on the left side among ten nozzle accommodating portions 64 on the front side of nozzle station 61 and eight nozzle accommodating portions 64 on the left side among ten nozzle accommodating portions 64 on the rear side are used. These two sets of eight nozzle accommodating portions 64 are provided at positions aligned with positions of eight second nozzle mounting sections 55 of transfer head 54. Therefore, by aligning the position of one second nozzle mounting section 55 of eight second nozzle mounting sections 55 with the position of any one of eight nozzle accommodating portions 64, the positions of all second nozzle mounting sections 55 are aligned with the positions of eight nozzle accommodating portions 64.

Specifically, as shown in FIG. 6, in transfer head 54 of the present example, four second nozzle mounting sections 55 arranged in the left-right direction at a predetermined pitch are provided to be arranged in two rows in the front-rear direction. As shown in FIG. 8, eight nozzle accommodating portions 64 for second suction nozzles 56 are provided at the same position or at the same pitch as second nozzle mounting sections 55, and four nozzle accommodating portions 64 arranged in the left-right direction are provided to be arranged in two rows in the front-rear direction.

Transfer head 54 moves, for example, above eight vacant nozzle accommodating portions 64 (for example, nozzle accommodating portions 64 on the rear side in FIG. 8) to align the positions of eight second nozzle mounting sections 55 with the positions of eight nozzle accommodating portions 64. Transfer head 54 drives Z-axis slide mechanism 53 to collectively lower eight second nozzle mounting sections 55 and inserts all second suction nozzles 56A into nozzle accommodating portions 64. Nozzle station mechanism 18 drives shutter drive section 65 to insert multiple (16 in total) engaging portions 63E into recessed portions (recessed portions having the same structure as those of recessed portions 41F of FIG. 9) of respective second nozzle mounting sections 55. Transfer head 54 drives Z-axis slide mechanism 53 to lift second nozzle mounting sections 55, so that second suction nozzles 56 can be removed from all second nozzle mounting sections 55.

Next, transfer head 54 moves above eight nozzle accommodating portions 64 (for example, nozzle accommodating portions 64 on the front side of FIG. 8) in which second suction nozzles 56B for exchange are accommodated, and the positions of eight second nozzle mounting sections 55 and the positions of eight second suction nozzles 56B (nozzle accommodating portions 64) are aligned. Nozzle station mechanism 18 drives shutter drive section 65 to align the positions of opening portions 63D with the positions of nozzle accommodating portions 64. Transfer head 54 drives Z-axis slide mechanism 53 to collectively lower eight second nozzle mounting sections 55 and mounts second suction nozzles 56B on all second nozzle mounting sections 55. Transfer head 54 lifts second nozzle mounting sections 55 to move second nozzle mounting sections 55 to predetermined initial positions or the like. Accordingly, exchange of first and second suction nozzles 43 and 56 can be completed.

Control device 19 drives lifting and lowering section 18B of nozzle station mechanism 18 to lower nozzle station 61 and drives wafer feed unit 12 to carry wafer frames 23 to be used for the next production out from magazine 24 to die feeding position P2. Control device 19 drives flip mechanism 15, transfer mechanism 16, wafer frame drawing mechanism 31, shuttle mechanism 17, and the like to start feeding of die 22 using first and second suction nozzles 43B and 56B after exchange.

The order and content of an operation in feeding of die 22 and exchange of first and second suction nozzles 43 and 56 described above are examples. For example, second suction nozzle 56 may be exchanged first, and first suction nozzle 43 may be exchanged later. Further, exchange of second suction nozzle 56 may be performed one by one without being performed collectively. Further, the positions of nozzle accommodating portions 64 that accommodate first and second suction nozzles 43 and 56 need not be determined in advance. For example, two nozzle accommodating portions 64 for first suction nozzles 43 may be set between four nozzle accommodating portions 64 for second suction nozzles 56 and remaining four nozzle accommodating portions 64 for second suction nozzles 56 in the left-right direction. In addition, as described above, since first and second suction nozzles 43 and 56 have the same structure, nozzle accommodating portions 64 for first and second nozzle mounting sections 41 and 55 need not be set, positions to be removed or positions to be mounted may be changed according to conditions. For example, exchange may be executed for nozzle accommodating portions 64 at a short distance.

Therefore, in the above example, control device 19 causes flip mechanism 15 to exchange first suction nozzles 43A and 43B and causes transfer mechanism 16 to exchange second suction nozzles 56A and 56B. In such a configuration, suction nozzles of the two heads can be automatically exchanged in one nozzle station 61 by control device 19.

In addition, nozzle station 61 is disposed at a position below die assembly 21 in a state in which die assembly 21 is disposed at die feeding position P2. According to this, in a case where first and second suction nozzles 43 and 56 are exchanged, die assembly 21 is retracted from die feeding position P2 to housing position P1, so that a space for exchange can be secured and the exchange can be performed. Therefore, first and second suction nozzles 43 and 56 can be exchanged at the same position as die assembly 21 in the front-rear direction or the left-right direction. In a case where nozzle station 61 is disposed at a position away from die feeding position P2, it is necessary to widen the movable range of flip head 35 or transfer head 54 in the front-rear direction or the left-right direction and to enable flip head 35 and transfer head 54 to operate up to nozzle station 61. On the other hand, by placing nozzle station 61 below die feeding position P2, it is not necessary to expand the movable range of flip head 35 or transfer head 54. Therefore, the size of flip mechanism 15 or transfer mechanism 16 can be reduced.

In addition, in a case where first and second suction nozzles 43 and 56 are exchanged, control device 19 moves die assembly 21 to housing position P1 and then causes lifting and lowering section 18B to lift nozzle station 61 to a position where first and second suction nozzles 43 and 56 can be exchanged. According to this, the amount of movement for lowering flip head 35 in a case of exchanging first and second suction nozzles 43 and 56 can be reduced. The movable range of flip head 35 in the up-down direction can be narrowed, and the size of Z-axis slide mechanism 34 can be reduced.

In addition, in a case where flip head 35 is moved to a position where die 22 can be picked up from die assembly 21 by first suction nozzles 43A mounted on first nozzle mounting sections 41, nozzle accommodating portions 64 accommodating first suction nozzles 43B for exchange are disposed at positions below first nozzle mounting sections 41 of flip head 35 (see FIG. 11). According to this, it is not necessary to move flip head 35 in the left-right direction in exchange of first suction nozzles 43A and 43B. Therefore, the number of movement shafts required as flip mechanism 15, specifically, a mechanism that moves in the left-right direction can be eliminated. The size and manufacturing costs of flip mechanism 15 can be reduced.

In addition, flip mechanism 15 slides flip head 35 in the front-rear direction to move flip head 35 to a position where die 22 is picked up and a position of being retracted from transfer head 54. The position of nozzle station 61 is fixed in the front-rear direction and the left-right direction. In addition, the position of flip head 35 in the left-right direction is fixed. Accordingly, a mechanism that moves flip head 35 in the left-right direction is unnecessary and a mechanism that moves nozzle station 61 in the front-rear direction or the left-right direction is also unnecessary, thereby reducing the size of the device and reducing manufacturing costs.

In addition, first suction nozzles 43 are mounted on first nozzle mounting sections 41 by magnetic forces of magnets 41D. Control device 19 causes shutter drive section 65 to move shutter 63 such that opening portions 63D are at positions of openings of nozzle accommodating portions 64. Next, control device 19 moves flip head 35 to insert first suction nozzles 43A into nozzle accommodating portions 64. Next, control device 19 causes shutter drive section 65 to move shutter 63 to a position where pair of engaging portions 63E are engaged with first suction nozzles 43A with first suction nozzles 43A inserted into nozzle accommodating portions 64. Then, control device 19 moves flip head 35 and engages engaging portions 63E with first suction nozzles 43A to remove first suction nozzles 43A from first nozzle mounting sections 41. Accordingly, for example, as compared with a configuration where engaging portion 91 and groove 93 are provided as shown in FIG. 12 to be described later, structures of first suction nozzles 43 or first nozzle mounting sections 41 can be simplified, and manufacturing costs can be reduced. In addition, in the configuration of FIG. 12, in an operation of attaching and detaching first suction nozzles 43, an operation of rotating first nozzle mounting sections 41 and the like is necessary. Therefore, it is necessary to provide a motor or the like for rotating first nozzle mounting sections 41 in flip head 35, and the structure of flip head 35 becomes complicated. On the other hand, by adopting a configuration where mounting is performed using magnets 41D and removal is performed using engaging portions 63E of shutter 63, attachment and detachment can be performed by movement of shutter 63 and vertical movement of flip head 35. The structure of flip head 35 can be simplified. In addition, by providing magnets 41D on a first nozzle mounting section 41 side, it is not necessary to provide a magnet in all first suction nozzles 43, and costs can be reduced.

In addition, in the present example, first suction nozzles 43 can be mounted on second nozzle mounting sections 55, and second suction nozzles 56 can be mounted on first nozzle mounting sections 41. Accordingly, compatibility between first and second suction nozzles 43 and 56 can be ensured. In an operation of placing first and second suction nozzles 43 and 56 for exchange in nozzle station 61, it is not necessary for the worker to be conscious of which of first and second suction nozzles 43 and 56 is, and can prepare nozzle station 61. Reduce the burden of an operation of placing first and second suction nozzles 43B and 56B in nozzle station 61 and management of first and second suction nozzles 43 and 56 are facilitated. Further, by using first and second suction nozzles 43 and 56 in common, manufacturing costs of first and second suction nozzles 43 and 56 or components related to first and second suction nozzles 43 and 56 can be reduced.

In the above example, wafer frame drawing mechanism 31 is an example of a die assembly moving mechanism. Revolving motor 38 is an example of an inverting mechanism. Transfer head 54 is an example of a feed head. Y-axis slide mechanism 33 and Z-axis slide mechanism 34 are examples of a flip head moving mechanism. X-axis slide mechanism 51, Y-axis slide mechanism 52, Z-axis slide mechanism 53 are examples of a feed head moving mechanism. The front-rear direction and the Y-axis direction are examples of a sliding direction of the present disclosure. The left-right direction and the X-axis direction are examples of an orthogonal direction of the present disclosure.

Hereinbefore, according to the example, the following effects are achieved. Both first suction nozzles 43B for exchange and second suction nozzles 56B for exchange are accommodated in nozzle station 61 of one aspect of the present example. According to this, in one nozzle station 61, both first suction nozzles 43B for exchange mounted on flip head 35 and second suction nozzles 56B for exchange mounted on transfer head 54 can be managed. Accordingly, the suction nozzles for exchange of the two heads can be collectively managed by one nozzle station 61 and can be exchanged at one place. Further, by controlling each of the heads, both first and second suction nozzles 43 and 56 can be automatically exchanged. Further, the workload of managing the suction nozzles for exchange, such as an operation of replacing the suction nozzles for exchange of nozzle station 61 and confirmation of the suction nozzles stored in nozzle station 61, can be reduced.

The content of the present disclosure is not limited to the above example, but can be carried out in various forms in which various changes and improvements are made based on the knowledge of those skilled in the art.

For example, in the above example, first nozzle mounting sections 41 and second nozzle mounting sections 55 have the same structure, but may have different structures.

In the above example, first suction nozzles 43 are mounted on first nozzle mounting sections 41 and second suction nozzles 56 are mounted on second nozzle mounting sections 55 by a magnetic force using magnetic members 73 and magnets 41D, but the present disclosure is not limited thereto. FIG. 12 shows first suction nozzle 143 and first nozzle mounting section 141 of another example. As shown in FIG. 12, main body portion 90 of first suction nozzle 143 may be provided with pair of engaging portions 91. Groove 93 that engages with engaging portion 91 may be provided on a first nozzle mounting section 141 side. For example, in a case where first suction nozzle 143 is attached, engaging portion 91 is inserted into groove 93 of first nozzle mounting section 141 from the axial direction, and first nozzle mounting section 141 is rotated to engage engaging portion 91 with groove 93, thereby attaching first suction nozzle 143 to first nozzle mounting section 141. In addition, spring 95 may be provided in first suction nozzle 143 to bias engaging portion 91 toward the first nozzle mounting section 141 side so that engaging portion 91 is not easily removed from groove 93. In addition, in the case of removal, first nozzle mounting section 141 is lowered to contract spring 95, and first nozzle mounting section 141 is rotated in a direction opposite to a direction in a case of mounting and then lifted to remove first suction nozzle 143 from first nozzle mounting section 141. In a case where the configuration of FIG. 12 is adopted, a mechanism that rotates the suction nozzle around an axis may be provided in transfer head 54, flip head 35, or nozzle station 61.

Further, flip mechanism 15 may include an X-axis slide mechanism and move flip head 35 in the left-right direction.

In addition, in the above example, transfer head 54 that delivers die 22 received from flip mechanism 15 to shuttle mechanism 17 is adopted as the feed head of the present disclosure, but the present disclosure is not limited thereto. The feed head of the present disclosure may be a mounting head that mounts die 22 received from flip mechanism 15 on a board. Therefore, the die feed device of the present disclosure is not limited to a device that feeds die 22 to shuttle mechanism 17 and may be a component mounter that mounts die 22 on the board.

In addition, in the above example, revolving motor 38 is adopted as the inverting mechanism of the present disclosure, but the present disclosure is not limited thereto. For example, a mechanism that rotates flip head 35 using an air cylinder may be adopted as the inverting mechanism.

Nozzle station 61 may be disposed at a position other than below die feeding position P2. In this case, nozzle station mechanism 18 need not include lifting and lowering section 18B.

Nozzle station mechanism 18 may include a mechanism that moves nozzle station 61 in the left-right direction or the front-rear direction.

### REFERENCE SIGNS LIST

10 die feed device, 17 shuttle mechanism, 17D shuttle, 18B lifting and lowering section, 19 control device, 21 die assembly, 22 die, 24 magazine, 31 wafer frame drawing mechanism (die assembly moving mechanism), 33 Y-axis slide mechanism (flip head moving mechanism), 34 Z-axis slide mechanism (flip head moving mechanism), 35 flip head, 38 revolving motor (inverting mechanism), 41, 141 first nozzle mounting section, 41D magnet, 43, 43A, 43B, 143 first suction nozzle, 51 X-axis slide mechanism (feed head moving mechanism), 52 Y-axis slide mechanism (feed head moving mechanism), 53 Z-axis slide mechanism (feed head moving mechanism), 54 transfer head (feed head), 55 second nozzle mounting section, 56, 56A, 56B second suction nozzle, 61 nozzle station, 63 shutter, 63D opening portion, 63E engaging portion, 64 nozzle accommodating portion, 65 shutter drive section, P1 housing position, P2 die feeding position, P5 receiving position, P6 delivery position.

1. A die feed device comprising:
a flip head including a first nozzle mounting section from which a first suction nozzle is detachably mounted, the flip head being configured to pick up a die with the first suction nozzle from a die assembly formed by dicing a wafer;
an inverting mechanism configured to invert the flip head and switches a front and a back of the die picked up by the first suction nozzle;
a feed head including a second nozzle mounting section from which a second suction nozzle is detachably mounted, the feed head being configured to pick up the die inverted by the flip head with the second suction nozzle and feed the die picked up by the second suction nozzle; and
a nozzle station configured to accommodate both the first suction nozzle for exchange and the second suction nozzle for exchange.

2. The die feed device according to claim 1, further comprising:
a flip head moving mechanism configured to move the flip head;
a feed head moving mechanism configured to move the feed head; and
a control device configured to control the flip head moving mechanism and the feed head moving mechanism,
wherein the control device
causes the flip head moving mechanism to exchange the first suction nozzle mounted on the first nozzle mounting section of the flip head with the first suction nozzle for exchange accommodated in the nozzle station, and
causes the feed head moving mechanism to exchange the second suction nozzle mounted on the second nozzle mounting section of the feed head with the second suction nozzle for exchange accommodated in the nozzle station.

3. The die feed device according to claim 1, further comprising:
a magazine configured to accommodate the die assembly; and
a die assembly moving mechanism configured to move the die assembly between a housing position and a die feeding position,
wherein the housing position is a position where the die assembly is housed in the magazine,
the die feeding position is a position where the die is picked up from the die assembly by the first suction nozzle, and
the nozzle station is disposed at a position below the die assembly in a state in which the die assembly is disposed at the die feeding position.

4. The die feed device according to claim 3, further comprising:
a lifting and lowering section configured to move the nozzle station in an up-down direction; and
a control device configured to control the lifting and lowering section,
wherein the control device
causes the die assembly moving mechanism to move the die assembly to the housing position in a case of performing exchange between the first suction nozzle and the first suction nozzle for exchange, and
causes, after the die assembly is moved to the housing position, the lifting and lowering section to lift the nozzle station to a position where the exchange between the first suction nozzle and the first suction nozzle for exchange is possible.

5. The die feed device according to claim 2,
wherein in the nozzle station, in a case where the flip head is moved by the flip head moving mechanism to a position where the die is capable of being picked up from the die assembly by the first suction nozzle mounted on the first nozzle mounting section, a nozzle accommodating portion configured to accommodate the first suction nozzle for exchange in the nozzle station is disposed at a position below the first nozzle mounting section of the flip head.

6. The die feed device according to claim 5, further comprising:
a lifting and lowering section configured to move the nozzle station in an up-down direction,
wherein the flip head moving mechanism slides the flip head in a sliding direction to change a position of the flip head in the sliding direction and moves the flip head to a position where the die is picked up by the first suction nozzle and a position where the die is retracted from the feed head,
the sliding direction is a direction perpendicular to the up-down direction,
in a case where a direction orthogonal to both the up-down direction and the sliding direction is defined as an orthogonal direction, a position of the nozzle station in the sliding direction and the orthogonal direction is fixed, and
a position of the flip head in the orthogonal direction is fixed.

7. The die feed device according to claim 2,
wherein a magnet is attached to at least one of the first suction nozzle or the first nozzle mounting section, and the first suction nozzle is held at the first nozzle mounting section by a magnetic force of the magnet,
the nozzle station further includes
a nozzle accommodating portion configured to accommodate the first suction nozzle,
a shutter including an opening portion that opens an opening of the nozzle accommodating portion, and an engaging portion, and
a shutter drive section configured to move the shutter, and
the control device
causes the shutter drive section to move the shutter such that the opening portion is at a position of the opening of the nozzle accommodating portion,
causes the flip head moving mechanism to move the flip head and inserts the first suction nozzle mounted on the first nozzle mounting section into the nozzle accommodating portion,
causes, in a state in which the first suction nozzle is inserted into the nozzle accommodating portion, the shutter drive section to move the shutter to a position where the engaging portion is engaged with the first suction nozzle, and
causes the flip head moving mechanism to move the flip head and engages the engaging portion with the first suction nozzle to remove the first suction nozzle from the first nozzle mounting section.

8. The die feed device according to claim 1,
wherein the first suction nozzle is mountable on the second nozzle mounting section, and
the second suction nozzle is mountable on the first nozzle mounting section.

9. The die feed device according to claim 1, further comprising:
a shuttle mechanism including a shuttle in which the die is disposable, the shuttle mechanism being configured to move the shuttle between a receiving position and a delivery position,
wherein the receiving position is a position where the die is received by the shuttle from the second suction nozzle of the feed head, and
the delivery position is a position where the die of the shuttle is acquired by a mounting head of a component mounter.
